(19) United States
(12) Patent Application Publication
(10) Pub. No.: US 2024/0332015 A1
(43) Pub. Date: Oct. 3, 2024

(54) METHODS OF FORMING APPARATUS COMPRISING CRYSTALLINE SEMICONDUCTOR MATERIALS AND METAL SILICIDE MATERIALS, AND RELATED APPARATUS

(71) Applicant: Micron Technology, Inc., Boise, ID (US)

(72) Inventors: Protyush Sahu, Boise, ID (US); Mikhail A. Treger, Boise, ID (US); Yi Fang Lee, Boise, ID (US); Jay S. Brown, Boise, ID (US); Shuai Jia, Boise, ID (US); Jaidah Mohan, Boise, ID (US); Silvia Borsari, Boise, ID (US); Richard Beeler, Boise, ID (US); Jeffery B. Hull, Boise, ID (US); Prashant Raghu, Boise, ID (US)

(21) Appl. No.: 18/427,756

(22) Filed: Jan. 30, 2024

Related U.S. Application Data
(60) Provisional application No. 63/493,165, filed on Mar. 30, 2023.

(51) Int. Cl. H01L 21/02; H01L 21/4763; H10B 12/00

(52) U.S. Cl. CPC H01L 21/02592; H01L 21/02598; H01L 21/47635; H10B 12/02

(57) ABSTRACT

A method of forming an apparatus comprises forming a crystalline semiconductor material comprising one or more of a monocrystalline material and a nanocrystalline material adjacent to active areas of memory cells, forming an amorphous material within portions of the crystalline semiconductor material, forming a metal material comprising one or more of chlorine atoms and nitrogen atoms over the amorphous material, converting a portion of the amorphous material and the metal material to form a metal silicide material adjacent to the crystalline semiconductor material, forming cell contacts over the metal silicide material, and forming a storage node adjacent to the cell contacts. Additional methods and apparatus are also disclosed.

### PRIORITY CLAIM

This application claims the benefit under 35 U.S.C. § 119(e) of U.S. Provisional Patent Application Ser. No. 63/493,165, filed Mar. 30, 2023, the subject matter of which is related to the subject matter of U.S. Application No. 63/493,157, titled “APPARATUS COMPRISING CRYSTALLINE SEMICONDUCTOR MATERIALS AND METAL SILICIDE MATERIALS, AND RELATED METHODS AND SYSTEMS,” filed on even date herewith, the disclosure of each of which is hereby incorporated herein in its entirety by this reference.

### TECHNICAL FIELD

Embodiments disclosed herein relate to the field of electronic device design and fabrication. More particularly, embodiments of the disclosure relate to methods of forming apparatus (e.g., electronic devices) including crystalline semiconductor materials (e.g., monocrystalline silicon material, nanocrystalline silicon material) and metal silicide materials, and to related apparatus.

### BACKGROUND

Electronic device designers desire to increase the level of integration or density of features within an electronic device by reducing the dimensions of individual features and by reducing the separation distance between neighboring features. In addition, electronic device designers often desire to design architectures that are not only compact, but offer performance advantages, as well as simplified designs. A relatively common electronic device is a memory device. A memory device may include a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In the simplest design configuration, a DRAM cell includes one access device (e.g., a transistor) and one storage device (e.g., a capacitor). Modern applications for memory devices may utilize vast numbers of DRAM unit cells, arranged in an array of rows and columns. The DRAM cells are electrically accessible through digit lines and access lines (e.g., word lines) arranged along the rows and columns of the array.

As the dimensions and spacing of the features decrease, contact resistance of the features increases due to the smaller feature sizes. To form contacts in conventional electronic devices, openings (e.g., contact holes) are formed that extend to active areas of the electronic device. Epitaxial growth of silicon is conducted in the openings and over the active areas, forming monocrystalline silicon, and an amorphous silicon interface is formed over the monocrystalline silicon using an implant process. The monocrystalline silicon and the amorphous silicon interface are doped with phosphorus. A metal silicide is then formed adjacent to the amorphous silicon interface. However, impurity regions including oxygen or chlorine, for example, may be introduced during formation of the contacts, which may result in detrimental effects (e.g., defects, such as voids) within (e.g., at the amorphous silicon interface of) the monocrystalline silicon. Presence of the impurity regions and defects may result in increased contact resistance of the electronic devices.

### BRIEF DESCRIPTION OF THE SEVERAL VIEWS OF THE DRAWINGS

FIG. 1 is a simplified, partial cross-sectional view of an apparatus including contact structures according to embodiments of the disclosure;

FIGS. 2A through 2D are simplified, partial cross-sectional views illustrating a method of forming the apparatus according to embodiments of the disclosure;

FIGS. 3A through 3D are simplified, partial cross-sectional views illustrating a method of forming the apparatus according to additional embodiments of the disclosure;

FIG. 4 is a functional block diagram of an electronic device in accordance with embodiments of the disclosure; and

FIG. 5 is a schematic block diagram of an electronic system in accordance with embodiments of the disclosure.

### DETAILED DESCRIPTION

Methods of forming an apparatus (e.g., an electronic device, a semiconductor device, a memory device) including crystalline semiconductor material (e.g., a monocrystalline silicon material, a nanocrystalline silicon material) are described herein, as are related apparatus. In some embodiments, a method of forming an apparatus comprises forming a crystalline semiconductor material comprising one or more of a monocrystalline material and a nanocrystalline material adjacent to (e.g., over, directly on) active areas of memory cells. The crystalline semiconductor material includes a dopant, such as an n-type dopant. An amorphous material may be formed within portions (e.g., upper portions) of the crystalline semiconductor material and a metal (e.g., titanium) comprising one or more of chlorine atoms and nitrogen atoms may be formed over the amorphous material. During the formation of the metal material, a portion of the amorphous material and the metal may be converted to form a metal silicide material (e.g., titanium silicide). Cell contacts may be formed over the metal silicide material and a storage node may be formed adjacent to the cell contacts. The crystalline semiconductor material, the amorphous material, if present, the metal silicide, and the metal material constitute a contact structure between an access device (e.g., a transistor) positioned adjacent to (e.g., below) the active areas and a storage device (e.g., storage node, a capacitor) over the metal material of the cell contacts.

The metal material may be formed by depositing a metal comprising titanium using a CVD process and annealing the metal to form the metal silicide material. The metal and a metal contact material of the cell contacts may be formed in a single, substantially continuous process, without forming a nitride barrier material over the metal silicide material. In some embodiments, the monocrystalline material may be epitaxially grown on the active areas of the memory cells, and the nanocrystalline material, if present, may be formed adjacent to the monocrystalline material. The monocrystalline material and the nanocrystalline material may be formed by a single, substantially continuous process in which the process conditions are varied. By varying the process conditions during the single, substantially continuous process, manufacturing processes for forming the apparatus may be simplified and costs may be reduced. Alternatively, an amorphous silicon material may be formed adjacent to the active areas of the memory cells and a laser anneal act, for example, may be conducted to convert the amorphous silicon material to the crystalline semiconductor material (e.g., a crystalline silicon material).

The crystalline semiconductor material may be exposed to annealing conditions to diffuse one or more dopants (e.g., phosphorus (P), germanium (Ge), arsenic (As), antimony (Sb)) from upper portions of the crystalline semiconductor material into lower portions thereof after performing a pre-amorphization implant (PAI) process and prior to forming the metal silicide material. The dopants diffuse into the silicon lattice of the crystalline semiconductor material. By selecting a precursor of the metal material that includes chlorine atoms (e.g., a titanium chloride material) and/or nitrogen atoms, an interface between the crystalline semiconductor material and the metal silicide material may be substantially free of defect regions including voids. While the precursor of the metal material has been described as being formed to include chlorine atoms and/or nitrogen atoms, the disclosure is not so limited and other configurations may be contemplated. For example, the metal material may, alternatively, be formed to be substantially free (e.g., substantially entirely free) of one or more (e.g., each) of chlorine atoms and nitrogen atoms. Further, the interface may be substantially free of impurity regions including, for example, oxygen atoms, chlorine atoms, and nitrogen atoms, by exposing the crystalline semiconductor material to a wet etch chemistry, such as hydrogen chloride (HCl), and/or the annealing conditions prior to forming the metal material. By improving the interface to form a so-called “non-defective, impurity-free interface,” the contact structures in the memory cells according to embodiments of the disclosure exhibit reduced contact resistance relative to contact structures of conventional memory cells.

In additional embodiments, forming the apparatus may include forming a first portion of the crystalline semiconductor material adjacent to the active areas of memory cells, and exposing the first portion of the crystalline semiconductor material to annealing conditions (e.g., first annealing conditions). A second portion of the crystalline semiconductor material may be formed over the first portion, and the first portion and the second portion of the crystalline semiconductor material may be exposed to additional annealing conditions (e.g., second annealing conditions) prior to forming the amorphous material. The first and second portions of the crystalline semiconductor material may be formed by separate process acts, such as by a cyclic process. In some embodiments, the first portion of the crystalline semiconductor material may include a relatively high doped region and the second portion may include a relatively low doped region, as a result of exposing the first portion of the crystalline semiconductor material to more than one (e.g., two) treatment acts including the annealing conditions and exposing the second portion of the crystalline semiconductor material to one (e.g., a single) treatment act including the annealing conditions.

By using more than one (e.g., two or more) separate material formation acts and using more than one (e.g., two or more) treatment acts including the anneal conditions in a cyclical process, the dopants may be diffused from the upper portions into the lower portions of the crystalline semiconductor material, and dopant activation in the apparatus may be enhanced. Further, the cyclical process may improve dopant segregation, as well as improving an interface between the active areas and the crystalline semiconductor material. By improving the dopant segregation and improving the interface between the active areas and the crystalline semiconductor material, the apparatus according to embodiments of the disclosure may exhibit improved electrical properties and reduced contact resistance in contacts exhibiting reduced feature sizes (e.g., equal to or less than about 15 nm) compared to conventional apparatus.

The following description provides specific details, such as material types, material thicknesses, and process conditions in order to provide a thorough description of embodiments described herein. However, a person of ordinary skill in the art would understand that the embodiments of the disclosure may be practiced without employing these specific details. Indeed, the embodiments of the disclosure may be practiced in conjunction with conventional apparatus fabrication techniques employed in the industry. In addition, the description provided below does not form a complete process flow for manufacturing an apparatus (e.g., an electronic device, a microelectronic device, a memory device, such as DRAM memory device). The structures described below do not form a complete apparatus. Only those process acts and structures necessary to understand the embodiments of the disclosure are described in detail below. Additional acts to form a complete apparatus from the structures may be performed by conventional fabrication techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “contact” means and includes a connection facilitating a conductive pathway between at least two structures of the apparatus. For example, in a DRAM device exhibiting a dual bit memory cell structure, a digit line contact is provided between a digit line and an access device (e.g., a transistor) formed in or above a substrate, and a storage device contact is formed between the access device and the storage device (e.g., a capacitor) where electrical charge may be stored.

As used herein, the term “contact structure” means and includes a connection structure including the crystalline semiconductor material, the metal silicide, and the metal material between the access device and the storage device.

As used herein, the term “epitaxial growth” means and includes a material formed by a growth process in which the to-be-formed material has a crystal orientation (e.g., a crystal form, a crystal state) substantially similar to the crystal orientation of the material on which it is formed.

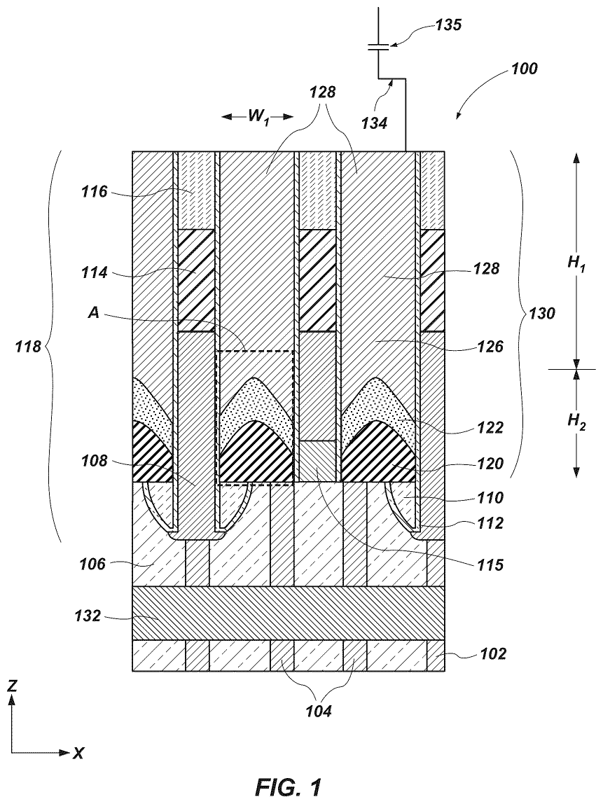

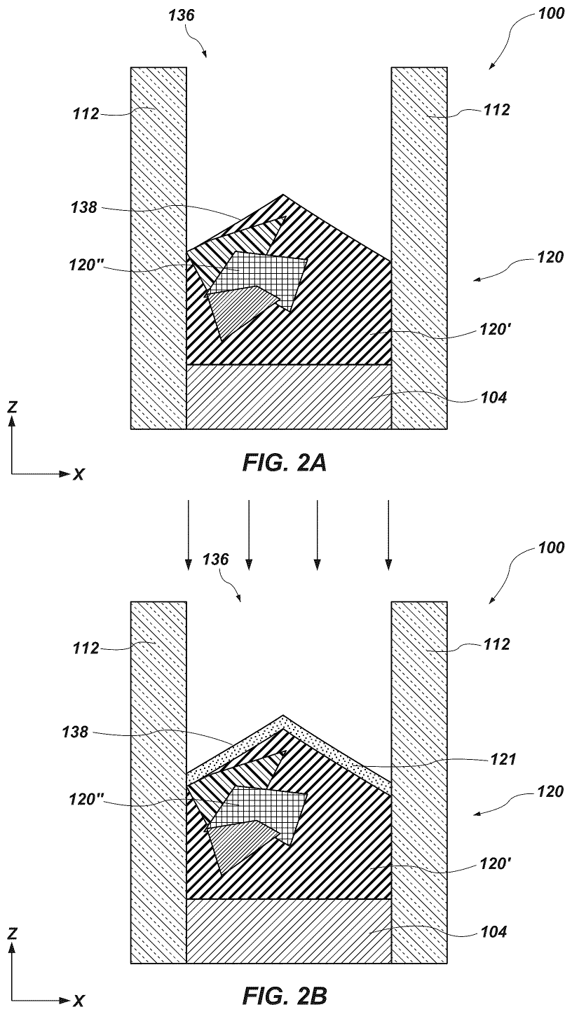

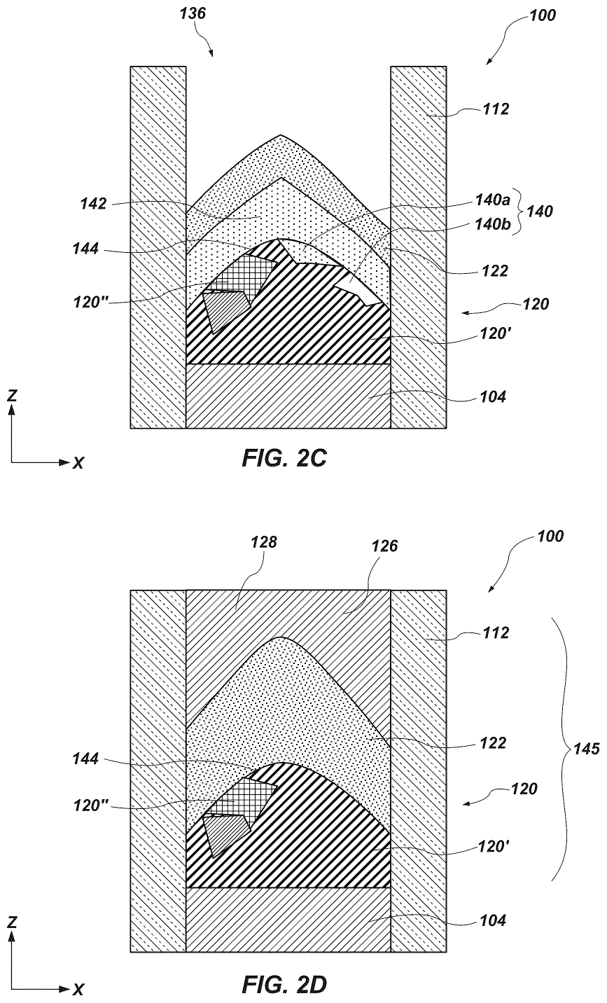

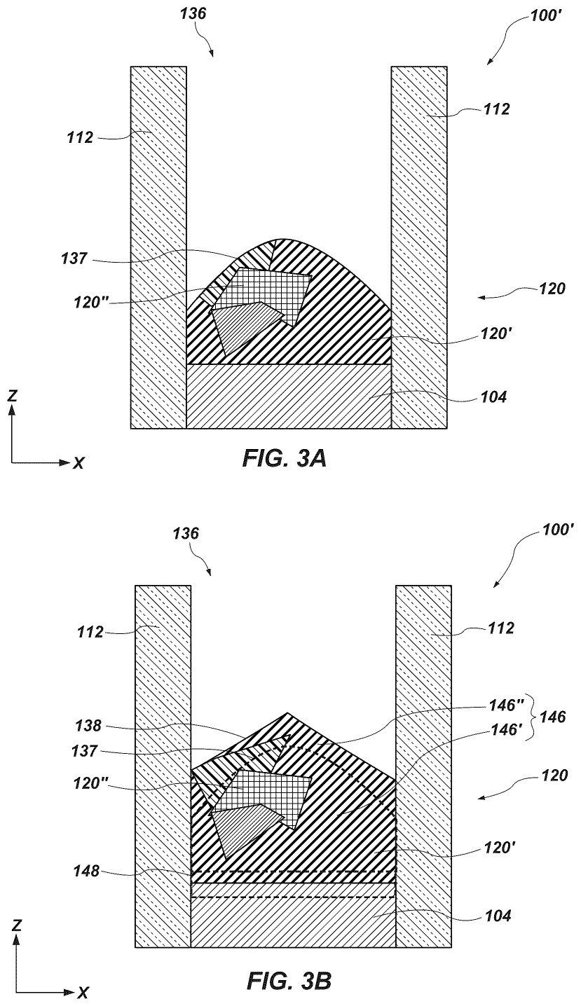

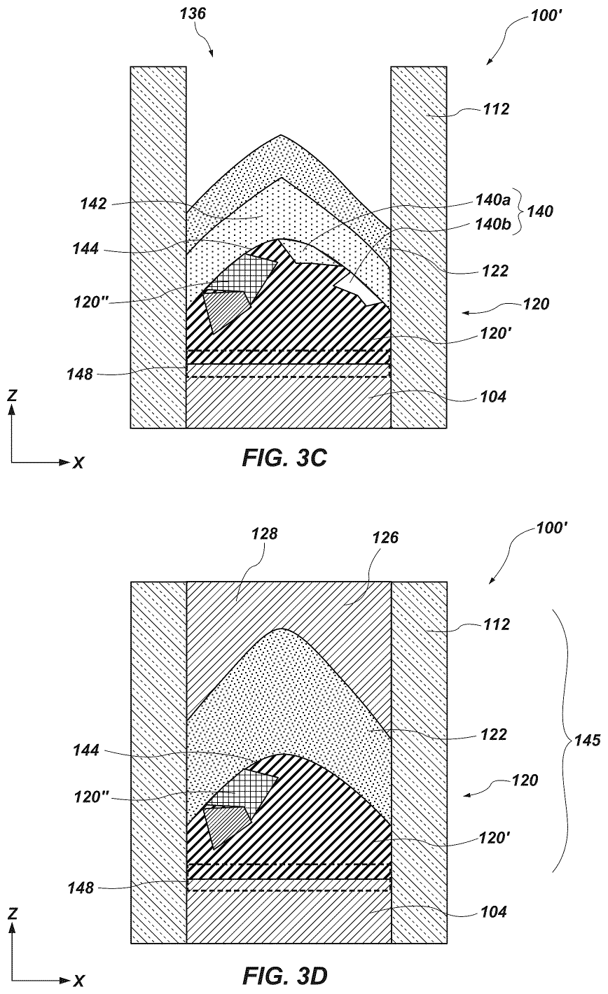

An apparatus 100 including a base material 102 (e.g., a substrate), active areas 104, shallow trench isolation (STI) structures 106, digit contacts 108, diffusion regions 110, insulative spacer material 112, digit lines 114, etch stop material 115, one or more insulative cap materials 116, crystalline semiconductor material 120 (e.g., epitaxial silicon material), metal silicide 122, and metal material 126 of cell contacts 128 (e.g., storage node contacts) is shown in FIG. 1, which is a cross-sectional view of the apparatus 100 in a first horizontal direction (e.g., a digit line direction). The apparatus 100 may optionally include an amorphous material 142 (not shown in FIG. 1) between the crystalline semiconductor material 120 and the metal silicide 122. For convenience in describing FIG. 1, the first horizontal direction may be defined as the X-direction and a second horizontal direction, which is transverse (e.g., perpendicular) to the first horizontal direction. A third direction, which is transverse (e.g., perpendicular) to each of the first horizontal direction and the second horizontal direction, may be defined as the Z-direction. Similar directions are defined, as shown in FIGS. 2A through 3D, as described in greater detail below.

Digit line structures 118 include the digit lines 114 and the materials (e.g., the digit contacts 108, the insulative cap material 116) vertically adjacent to the digit lines 114. The crystalline semiconductor material 120 is on (e.g., directly on, directly contacts) the active areas 104 and the STI structures 106, as shown in FIG. 1. The crystalline semiconductor material 120 (e.g., monocrystalline silicon material) may exhibit a monocrystalline orientation. Additionally, or alternatively, the crystalline semiconductor material 120 may comprise a nanocrystalline material (e.g., nanocrystalline silicon material) exhibiting differing (e.g., multi-directional) crystal orientations. The metal silicide 122 is adjacent to (e.g., on or over) the crystalline semiconductor material 120, and the metal material 126 of the cell contact 128 is on (e.g., directly on, directly contacts) the metal silicide 122. The crystalline semiconductor material 120, the metal silicide 122, and the cell contacts 128 constitute contact structures 130 and separate adjacent digit line structures 118 including the digit lines 114 from one another in the first horizontal direction (e.g., the digit line direction). In the second horizontal direction (e.g., an access line direction), the contact structures 130 (e.g., the crystalline semiconductor material 120, the metal silicide 122, and the cell contacts 128) are positioned over the STI structures 106.

The apparatus 100 also includes access lines 132 (e.g., word lines). The access lines 132 may be formed of and include an electrically conductive material including, but not limited to, one or more of a metal (e.g., tungsten, titanium, nickel, platinum, gold), a metal alloy, a metal-containing material (e.g., metal nitrides, metal silicides, metal carbides, metal oxides), and a conductively doped semiconductor material (e.g., conductively doped silicon). By way of non-limiting example, the access lines 132 may individually comprise one or more of W, TiN, TaN, WN, TiAIN, Ti, Pt, Rh, Ir, IrOₓ, Ru, RuOₓ, and alloys thereof. In some embodiments, the access lines 132 are formed of tungsten. The access lines 132 are isolated from one another by the STI structures 106.

As shown in FIG. 1, redistribution material (RDM) structures 134 (also referred to as “redistribution layer (RDL) structures”) may be formed on or over the cell contacts 128, and storage node structures 135 may be in electrical communication with the RDM structures 134 and the cell contacts 128. The RDM structures 134 may be configured to effectively shift (e.g., stagger, adjust, modify) lateral positions (e.g., in the X-direction, in a second horizontal direction, transverse to the X-direction) of the cell contacts 128 to accommodate a desired arrangement (e.g., a hexagonal close packed arrangement) of the storage node structures 135 over and in electrical communication with the cell contacts 128. The RDM structures 134 may be formed of and include one or more of the previously mentioned electrically conductive materials. The RDM structures 134 may be configured and formulated to couple (e.g., physically couple, electrically couple) the cell contacts 128 of the contact structures 130 to the storage node structures 135. The storage node structures 135 may be configured to store a charge representative of a programmable logic state. For example, a charged state of the storage node structures 135 may represent a first logic state (e.g., a logic 1), and an uncharged state of the storage node structures 135 may represent a second logic state (e.g., a logic 0). By way of example only, the cell contacts 128 may correspond to a landing pad for the storage node structures 135, such as a capacitor. For convenience, only one of the contact structures 130 is illustrated as including the RDM structure 134 and the storage node structure 135 in FIG. 1, although it is understood that each of the contact structures 130 may include the RDM structure 134 and the storage node structure 135.

Openings (e.g., contact openings) are defined by sidewalls (e.g., substantially straight, vertical sidewalls without voids or spaces) of the insulative spacer material 112. A width W₁ of the openings between adjacent portions of the insulative spacer material 112 of the digit line structures 118 may be within a range of from about 4 nm to about 20 nm, such as from about 4 nm to about 6 nm, from about 6 nm to about 8 nm, from about 8 nm to about 10 nm, from about 10 nm to about 15 nm, or from about 15 nm to about 20 nm. However, the disclosure is not so limited and the width W₁ may be different than those described above. In some embodiments, the width W₁ may be equal to or less than about 10 nm (e.g., about 8 nm). The width W₁ may be selected and tailored to effect a size and shape of one or more features (e.g., the cell contacts 128) of the apparatus 100.

The cell contacts 128 of the contact structures 130 may individually exhibit a first height H₁, and a combination of the crystalline semiconductor material 120 and the metal silicide 122 (e.g., defining a conductive plug) of the contact structures 130 may exhibit a second height H₂ that is relatively less than the first height H₁ of the cell contacts 128. The first height H₁ of the cell contacts 128 is greater than or equal to a combined thickness of additional materials of the contact structures 130 underlying the cell contacts 128. Accordingly, the first height H₁ corresponds to the vertical thickness of the cell contacts 128 and is relatively greater than the second height H₂ of the crystalline semiconductor material 120, the metal silicide 122, and additional materials adjacent thereto. The first height H₁ of the cell contacts 128, may be within a range of from about 15 nm to about 200 nm, such as from about 15 nm to about 40 nm, from about 40 nm to about 80 nm, from about 80 nm to about 120 nm, from about 120 nm to about 160 nm, or from about 160 nm to about 200 nm. The second height H₂ of the materials of the contact structures 130 underlying the cell contacts 128, may be within a range of from about 10 nm to about 65 nm, such as from about 10 nm to about 20 nm, from about 20 nm to about 30 nm, from about 30 nm to about 40 nm, from about 40 nm to about 50 nm, or from about 50 nm to about 65 nm. However, the disclosure is not so limited and the first height H₁ and the second height H₂ may be different than those described above.

FIGS. 2A through 2D are simplified, partial cross-sectional views illustrating embodiments of forming the apparatus 100 (e.g., an electronic device, a memory device, such as a DRAM device) including the contact structures 130 (FIG. 1). FIGS. 2A through 2D illustrate an enlarged portion of box A of FIG. 1. For clarity and case of understanding the drawings and associated descriptions, surrounding materials (e.g., the diffusion regions 110) are absent from FIGS. 2A through 2D, as well as from FIGS. 3A through 3D. With the description provided below, it will be apparent to one of ordinary skill in the art that the methods described herein may be used in the fabrication of various electronic devices and not only DRAM devices.

As shown in FIG. 2A, the active areas 104 are formed in the base material 102 (FIG. 1) that has been subjected to previous fabrication acts to form features thereon or therein. The base material 102 may include a conventional silicon substrate (e.g., a conventional silicon wafer), or another bulk substrate comprising a semiconductive material. In some embodiments, the base material 102 includes different materials, structures, devices, and/or regions formed thereon and/or therein. In some embodiments, the base material 102 includes complementary metal-oxide-semiconductor (CMOS) circuitry and devices configured for effectuating operation of memory cells of the apparatus 100. The active areas 104 are formed from monocrystalline silicon, such as doped monocrystalline silicon, and may be isolated from one another by the STI structures 106 (FIG. 1), which are formed from silicon dioxide (SiO₂). By way of example only, the active areas 104 may be formed of n-doped silicon.

Prior to forming the contact structures 130 (FIG. 1), the digit line structures 118 (FIG. 1) may be formed adjacent to (e.g., over) exposed portions of the active areas 104. The digit line structures 118 include the insulative spacer material 112 laterally adjacent to the digit contacts 108 (FIG. 1), the digit lines 114 (FIG. 1), and the insulative cap material 116 (FIG. 1). The digit lines 114 may be formed of and include one or more of the previously mentioned electrically conductive materials. The digit line structures 118 may also include additional vertically adjacent materials, such as a barrier metal material between the digit contacts 108 and the digit lines 114, as well as additional materials and structures (e.g., digit line caps) adjacent to (e.g., over) the insulative cap material 116. The materials and structures of the digit line structures 118 are formed by conventional techniques.

Additional portions of the active areas 104 are laterally separated from the active areas 104 underlying the digit line structures 118 (FIG. 1) by the insulative spacer material 112. The insulative spacer material 112 may be formed of and include an insulative material such as, for example, one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the insulative spacer material 112 comprises SiO₂.

The crystalline semiconductor material 120 (e.g., epitaxial silicon) may be formed (e.g., epitaxially grown) over the STI structures 106 (FIG. 1) and the active areas 104. The crystalline semiconductor material 120 is formed over the active areas 104 and between the insulative spacer material 112 of the digit line structures 118 (FIG. 1). For example, openings 136 (e.g., contact openings, contact holes) may be formed between laterally adjacent portions of the insulative spacer material 112, and the crystalline semiconductor material 120 may be formed within the openings 136, as shown in FIG. 2A. The openings 136 are defined by sidewalls of the insulative spacer material 112, an upper surface of the active areas 104, and an upper surface of the STI structures 106 (FIG. 1). The openings 136 extend to the active areas 104 and the STI structures 106 in the first horizontal direction (e.g., the X-direction). The crystalline semiconductor material 120 is formed on one or more (e.g., two) of the diffusion regions 110 (FIG. 1). In some embodiments, the diffusion regions 110 are formed from monocrystalline silicon. The crystalline semiconductor material 120 may be formed to exhibit an upper boundary 138 (e.g., an upper surface).

The crystalline semiconductor material 120 may include multiple (e.g., two or more) materials having distinct boundaries (e.g., interfaces) therebetween. By way of example, the crystalline semiconductor material 120 may be formed to include one or more of a monocrystalline material 120′ and a nanocrystalline material 120″. For clarity and case of understanding the drawings and associated descriptions, the nanocrystalline material 120″ includes multiple crosshatchings to illustrate multi-directional crystal orientations within the nanocrystalline material 120″. The crystalline semiconductor material 120 may be substantially devoid of polycrystalline material. Forming (e.g., epitaxially growing) the silicon of the crystalline semiconductor material 120 (e.g., the monocrystalline material 120′) adjacent to (e.g., over) the active areas 104 enables the silicon to be formed in the monocrystalline (e.g., single crystal) orientation. The silicon of the active areas 104 functions as a seed material to orient the crystal form of the monocrystalline material 120′.

The monocrystalline material 120′ functions as a seed material to orient one or more additional crystal forms of the nanocrystalline material 120″, indicated by the multiple crosshatchings used for the nanocrystalline material 120″. Formation of the nanocrystalline material 120″ by selective epitaxy, for example, may include using natural formation of one or more of so-called “twin plane defects” (e.g., planar defects) and so-called “stacking faults” (e.g., errors occurring in sequences of layers of atoms in crystalline materials) to transition to nanocrystalline growth. The nanocrystalline material 120″ may include one or more of single-phase and multiphase nano-sized crystals. The monocrystalline material 120′ may include a highly ordered crystalline material, and the nanocrystalline material 120″ may include a highly disordered crystalline material including multi-directional crystal orientations therewithin and including low growth rate facets. A crystal orientation of the nanocrystalline material 120″ may differ from a crystal orientation of the monocrystalline material 120′. In some embodiments, the monocrystalline material 120′ exhibits a (100) silicon crystal orientation and the nanocrystalline material 120″ exhibits a (111) silicon crystal orientation (e.g., inclined facets). Alternatively, the crystalline semiconductor material 120 may be formed to include the monocrystalline material 120′, without including the nanocrystalline material 120″. In additional embodiments, the crystalline semiconductor material 120 includes the nanocrystalline material 120″ directly adjacent to the active areas 104, without including the monocrystalline material 120′, as described below.

One or more of the monocrystalline material 120′ and the nanocrystalline material 120″ of the crystalline semiconductor material 120 may be formed in the openings 136 by an epitaxial growth process and substantially completely fill lower portions of the openings 136, without being formed in upper portions thereof. The crystalline semiconductor material 120 may be formed in the openings 136 without substantially removing portions of the insulative spacer material 112. Accordingly, the insulative spacer material 112 includes substantially straight, vertical sidewalls, without voids or spaces (e.g., gaps). The monocrystalline material 120′ and the nanocrystalline material 120″ are formed by a single, substantially continuous process in which the process conditions are varied (e.g., changed) such that the process conditions do not remain constant as both the monocrystalline material 120′ and the nanocrystalline material 120″ are formed. Without being bound by any theory, the substantially continuous, epitaxial growth process with varying process conditions may enable the monocrystalline material 120′ and the nanocrystalline material 120″ to be formed without forming native oxides at boundaries therebetween.

The substantially continuous, epitaxial growth process may include, for example, removing native oxides (if present) on the surface of the active areas 104 and flowing a silicon precursor, such as silane (SiH₄) gas, in the openings 136 at an initial temperature of about 470° C. and an initial pressure of about 1.2 Torr to form the monocrystalline material 120′, although other process conditions may be contemplated. Thereafter, one or more of the process conditions may be varied to form the nanocrystalline material 120″. For example, one or more of temperature, pressure, dopant concentration, dopant species, precursors, and gas flow rates of the silicon precursor may be varied as appropriate for formation of the nanocrystalline material 120″ adjacent to (e.g., over) the monocrystalline material 120′. As a non-limiting example, the silicon precursor may comprise silicon atoms and at least one ligand comprising one or more of hydrogen, nitrogen, and carbon, such as analkylamido silane compound. The silicon precursor may include, but is not limited to, silane (SiH₄), disilane (DiSi), dichlorosilane (DCS), tris(dimethylamido) silane (TDMAS), or combinations thereof. In some embodiments, the silicon precursor is DCS. Therefore, one or more (e.g., both) monocrystalline (e.g., single crystal) and additional crystalline (e.g., nanocrystalline) forms of silicon may be formed in the openings 136 by a single, substantially continuous process. By way of example only, the crystalline semiconductor material 120 may be a doped crystalline silicon material formed using DCS and phosphine (PH₃). After formation, HCl may be used to clean the crystalline semiconductor material 120. However, one or more of oxygen atoms, chlorine atoms, and nitrogen atoms may remain (e.g., may be present) in the crystalline semiconductor material 120 following the cleaning act.

In some embodiments, the monocrystalline material 120′ is formed initially in the openings 136, such that the monocrystalline material 120′ is directly adjacent to (e.g., directly on) upper surfaces of the active areas 104. The nanocrystalline material 120″, if present, may be subsequently formed adjacent to (e.g., directly adjacent to, directly over) the monocrystalline material 120′. The crystalline semiconductor material 120 may include regions of the nanocrystalline material 120″ embedded within the monocrystalline material 120′ or, alternatively, the nanocrystalline material 120″ may be formed over upper surfaces of the monocrystalline material 120′. In some embodiments, the monocrystalline material 120′ may vertically intervene between the active areas 104 and the nanocrystalline material 120″.

Without being bound by any theory, it is believed that the epitaxial growth of the crystalline semiconductor material 120 (e.g., the monocrystalline material 120′) over the active areas 104 and STI structures 106 (FIG. 1) occurs due to the crystal orientation of the silicon of the active areas 104. The crystal orientation of the active areas 104 affects the crystal orientation of the subsequently formed crystalline semiconductor material 120. As the epitaxial growth of the crystalline semiconductor material 120 proceeds towards and up the sidewalls of the insulative spacer material 112 (defining the openings 136) and as the process conditions are varied, an initial crystal orientation of the silicon of the monocrystalline material 120′ changes to an additional crystal orientation of the silicon of the nanocrystalline material 120″. Accordingly, the formation of the monocrystalline material 120′ stops and changes (e.g., transitions) to formation of the nanocrystalline material 120″.

A location at which the monocrystalline material 120′ changes to the nanocrystalline material 120″ may be controlled by adjusting (e.g., tuning, tailoring) one or more of the process conditions (e.g., temperature, pressure, dopant concentration, dopant species, precursors, and gas flow rates) upon formation of the monocrystalline material 120′. The monocrystalline material 120′ may be formed in the openings 136 to an initial thickness (e.g., height) by the epitaxial growth process and the nanocrystalline material 120″ may be formed adjacent to (e.g., over) the monocrystalline material 120′ by the epitaxial growth process. Therefore, a single, continuous epitaxial growth process is used to form the crystalline semiconductor material 120. A combined thickness of the monocrystalline material 120′ and the nanocrystalline material 120″ may be controlled by adjusting the process conditions in which the crystalline semiconductor material 120 is formed. By way of non-limiting example, the crystalline semiconductor material 120 may be formed in the openings 136 at a thickness of from about 15 nm to about 65 nm, although other thicknesses may be contemplated.

The crystalline semiconductor material 120 may be subsequently doped. For example, the crystalline semiconductor material 120 may be doped, such as with an n-type dopant. The monocrystalline material 120′ and the nanocrystalline material 120″ of the crystalline semiconductor material 120 may, for example, be implanted with phosphorus atoms (e.g., P-doped crystalline semiconductor material 120) or other dopant atoms. The doping of the crystalline semiconductor material 120 may be conducted by conventional techniques. In some embodiments, the monocrystalline material 120′ is P-doped crystalline semiconductor material 120, and the nanocrystalline material 120″ is P-doped crystalline semiconductor material 120. The nanocrystalline material 120″ may include a different (e.g., greater than) dopant concentration than a dopant concentration of the monocrystalline material 120′.

In additional embodiments, the crystalline semiconductor material 120 includes the nanocrystalline material 120″ (e.g., only) without including the monocrystalline material 120′. The nanocrystalline material 120″ may be formed directly adjacent to (e.g., directly on) the upper surfaces of the active areas 104 without forming the monocrystalline material 120′ adjacent to the active areas 104 (e.g., intervening between the nanocrystalline material 120″ and the active areas 104). The nanocrystalline material 120″ may be formed adjacent to the active areas 104 by varying the process conditions during formation of the crystalline semiconductor material 120. In some embodiments, the contact structures 130 (FIG. 1) are substantially devoid of monocrystalline material above the upper surfaces of the active areas 104. Accordingly, relative volumes of the nanocrystalline material 120″ within the crystalline semiconductor material 120 may be within a range of from about 50 percent to about 100 percent (e.g., substantially entirely nanocrystalline material). In embodiments including the nanocrystalline material 120″ without including the monocrystalline material 120′, the crystalline semiconductor material 120 may be substantially devoid of facets.

While formation of the crystalline semiconductor material 120 has been described as including the epitaxial growth process, the disclosure is not so limited. In additional embodiments, the crystalline semiconductor material 120 may be formed by conducting one or more anneal acts (e.g., a laser anneal act) on an amorphous material (e.g., an amorphous silicon material). The amorphous material may be formed on the active areas 104 and exposed to laser annealing conditions to form the crystalline semiconductor material 120. Therefore, the crystalline semiconductor material 120 may be formed without using the epitaxial growth process. In some embodiments, the crystalline semiconductor material 120 may be formed by forming one or more materials (e.g., amorphous material) within the openings 136 and thereafter conducting the anneal acts (e.g., the laser anneal act, ultra-violet laser annealing (UV-LA)). The anneal acts may include impinging laser light onto the materials within the openings 136 to form the crystalline semiconductor material 120. The amorphous material comprising silicon, for example, may be formed within the openings 136. Thereafter, the amorphous material may be converted to crystalline material (e.g., crystalline silicon material) using the anneal acts. The material may convert from amorphous to crystalline form upon exposure to an anneal temperature. Accordingly, the crystalline semiconductor material 120 may be formed using the anneal acts, without epitaxially growing crystalline materials (e.g., the monocrystalline material 120′) over the active areas 104. In additional embodiments, the monocrystalline material 120′ may be formed over the active areas 104 using the epitaxial growth process, and the laser anneal act may be performed thereafter to repair any damage that may have occurred within the monocrystalline material 120′ during the implant process acts.

Referring to FIG. 2B, one or more process acts may, optionally, be performed to form treated portions 121 of the crystalline semiconductor material 120 (e.g., proximate to the upper boundary 138 thereof). For example, the crystalline semiconductor material 120 may be subjected to (e.g., exposed to) one or more treatment acts (indicated by arrows) that change (e.g., increase) the chlorine content of desired portions (e.g., upper portions) of the crystalline semiconductor material 120. For instance, the upper portions may include a greater concentration of chlorine than lower portions due to the presence of chlorine in the crystalline semiconductor material 120 following the cleaning act. The upper portions may also include a greater concentration of the dopant than lower portions. The treatment acts may change the chemical composition of the exposed portions of the crystalline semiconductor material 120 compared to the composition of the crystalline semiconductor material 120, as initially formed.

The treatment acts may include exposing the crystalline semiconductor material 120 to a wet etch chemistry. In some embodiments, the wet etch chemistry may include hydrogen chloride (HCl). In some embodiments, excess portions of one or more of the monocrystalline material 120′ and the nanocrystalline material 120″ of the crystalline semiconductor material 120 may be removed by an in situ material removal (e.g., etch) act using the HCl. A flow rate of HCl may be reduced and an amount of time allotted to flow the HCl may be increased to reduce damage of surrounding materials during the treatment acts. Diffusion of the HCl into the crystalline semiconductor material 120 may allow a relatively greater concentration of chlorine atoms to achieve a desired chemical composition within the treated portions 121 of the crystalline semiconductor material 120. The treatment acts including the HCl may allow the chlorine atoms to diffuse homogeneously throughout portions (e.g., the upper portions) of the crystalline semiconductor material 120 (e.g., proximate to the upper boundary 138 thereof). In other embodiments, formation of the treated portions 121 of the crystalline semiconductor material 120 may result in the increased chlorine content therein, without excess portions of the crystalline semiconductor material 120 being removed. The greater concentration of chlorine atoms in the treated portions 121 of the crystalline semiconductor material 120 may result in a greater concentration of the dopant in the treated portions 121 of the crystalline semiconductor material 120. In other words, both the dopant and the chlorine atoms may accumulate proximal to the interface between the crystalline semiconductor material and the metal silicide material following treatment acts. In additional embodiments, the HCl may be formed during subsequently-conducted process acts, such as metallization process acts, without the HCl being introduced at the processing stage of FIG. 2B. For instance, HCl may be formed during the deposition of the metal, such as titanium, using a metal precursor material.

For convenience, the treated portions 121 of the crystalline semiconductor material 120 are described and illustrated at the processing stage of FIG. 2B, although it is understood that the treated portions 121 may be present in the crystalline semiconductor material 120 at subsequent processing stages (e.g., at the processing stage of FIG. 2D) of the apparatus 100. Without being bound by any theory, it is believed that the greater concentration of chlorine atoms, as well as the homogeneous distribution thereof, may facilitate reactions with chemical species, such as metal species, formed during subsequent process acts (e.g., metallization). By increasing the concentration of chlorine atoms within the treated portions 121 of the crystalline semiconductor material 120, contact resistance of the apparatus 100 may be reduced and thermal stability of the materials may be increased, as a result of improved conditions at an interface between the crystalline semiconductor material 120 and overlying materials. By way of example only, the contact resistance of the apparatus 100 may be less than or equal to about 45 kOhm/cell.

As shown in FIG. 2C, at least a portion of the crystalline semiconductor material 120, including the treated portions 121, may be converted to an amorphous material 142 (e.g., an amorphous silicon material). As used herein, the term “amorphous,” when referring to a material, means and refers to a material having a substantially noncrystalline structure. The amorphous material 142 may, optionally, be formed by an implant (Pre-Amorphization Implant (PAI)) process. For example, the crystalline semiconductor material 120 may be subjected to the implant process using one or more of germanium (Ge), phosphorus (P), arsenic (As), and antimony (Sb) to form the amorphous material 142 (e.g., an n-doped amorphous silicon material) over remaining portions of the crystalline semiconductor material 120. In some embodiments, the implant process includes using antimony. In other embodiments, the implant process includes using arsenic. Without being bound by any theory, it is believed that using one or more of antimony atoms and arsenic atoms (e.g., relatively heavy atoms) may allow a greater concentration of the n-type dopants within the crystalline semiconductor material 120, while reducing damage within portions (e.g., lower portions) that are remote from the upper boundary 138 (FIG. 2B) thereof.

In some embodiments, only a portion (e.g., the upper portion) of the crystalline semiconductor material 120 may be converted to the amorphous material 142 and additional portions (e.g., the lower portions) of the crystalline semiconductor material 120 may remain in the apparatus 100. In some embodiments, the nanocrystalline material 120″ (e.g., a sacrificial nanocrystalline material) may be within the upper portions of the crystalline semiconductor material 120 and may be substantially completely converted to the amorphous material 142 such that the contact structures 130 (FIG. 1) are substantially devoid of the nanocrystalline material 120″. In other embodiments, one or more (e.g., each) of the monocrystalline material 120′ and the nanocrystalline material 120″ may remain in the apparatus 100.

Further, the treated portions 121 of the crystalline semiconductor material 120 may be at least partially (e.g., substantially completely) converted to the amorphous material 142 such that portions of the amorphous material 142 include the relatively greater concentration of chlorine atoms and the dopant proximate to the upper boundary 138 (FIG. 2B) of the crystalline semiconductor material 120. The amorphous material 142 may directly contact the crystalline semiconductor material 120 along an interface 144 (corresponding to the upper boundary 138 of the crystalline semiconductor material 120). Lower surfaces of the amorphous material 142 may be in direct physical contact with the upper boundary 138 of the crystalline semiconductor material 120 along the interface 144 (e.g., horizontal interface) therebetween. Thus, the amorphous material 142 may be directly adjacent to the crystalline semiconductor material 120.

Formation of the crystalline semiconductor material 120 followed by formation of the amorphous material 142 using the implant process may, in some instances, result in damage to the crystalline semiconductor material 120. The crystalline semiconductor material 120 may, therefore, include localized regions 140 including one or more of impurity regions 140a and defect regions 140b. The impurity regions 140a may, for example, include one or more of oxygen atoms, chlorine atoms, and nitrogen atoms. For example, the impurity regions 140a may be formed at least in part by forming an increased concentration of one or more dopants (e.g., phosphorus) and by the implant process used to form the amorphous material 142. It is believed that a greater concentration of the dopant atoms within the upper portions of the crystalline semiconductor material 120 may result in a higher concentration of chlorine atoms of the impurity regions 140a. The defect regions 140b may include voids (e.g., gaps, spaces) separating adjacent regions of the crystalline material of the crystalline semiconductor material 120 from one another.

The localized regions 140 may individually be separated from one another by portions of the crystalline semiconductor material 120. In some embodiments, some of the localized regions 140 may be substantially surrounded by the crystalline semiconductor material 120. In other embodiments, some of the localized regions 140 may be adjacent a perimeter of the crystalline semiconductor material 120 (e.g., adjacent to one or more of the insulative spacer material 112 and the interface 144 between the amorphous material 142 and the crystalline semiconductor material 120). Further, some of the localized regions 140 may be adjacent to one another (e.g., the impurity regions 140a may be adjacent to the defect regions 140b). For convenience, the localized regions 140 are described and illustrated at the processing stage of FIG. 2C, although it is understood that one or more of the impurity regions 140a and the defect regions 140b may be present in the crystalline semiconductor material 120 during the formation thereof (e.g., at the processing stage of FIG. 2A). Additional localized regions 140 may be formed during the implant process used to form the amorphous material 142.

After forming the amorphous material 142 using the implant process and prior to converting the amorphous material 142 to the metal silicide 122, one or more additional process acts may, optionally, be performed. For example, the amorphous material 142 and the crystalline semiconductor material 120 may be subjected to (e.g., exposed to) one or more treatment acts that change distribution of the dopants throughout the materials. The treatment act may diffuse the dopants through (e.g., from the upper portions to lower portions of) the amorphous material 142 and the crystalline semiconductor material 120. The treatment act may include exposing the materials to annealing conditions including, for example, rapid thermal anneal (RTA) conditions. Accordingly, the crystalline semiconductor material 120 may, optionally, be annealed (e.g., thermally annealed) after forming the amorphous material 142 using the implant act and before formation of the metal silicide 122 and the metal material 126 (FIG. 2D). Exposing the crystalline semiconductor material 120 to the annealing conditions prior to converting the amorphous material 142 to the metal silicide 122 may diffuse the dopants from the upper portions into the lower portions of the crystalline semiconductor material 120, and may also facilitate or enhance dopant activation. The dopant is diffused into the lattice of the crystalline semiconductor material 120 and improves damage to the crystalline semiconductor material 120 caused by the implant process.

Without being bound by any theory, it is believed that performing the treatment acts including exposing the crystalline semiconductor material 120 to one or more of the wet etch chemistry (e.g., HCl) and the annealing conditions before forming the metal silicide 122 may decrease the presence of localized regions 140 including the impurity regions 140a and the defect regions 140b, which results in reduced defects along the interface 144 of the amorphous material 142 and the crystalline semiconductor material 120. For example, the treatment acts may facilitate reduced volumes of oxygen atoms, chlorine atoms, and/or nitrogen atoms of the impurity regions 140a, as well as reduced voids of the defect regions 140b, proximate to the interface 144. Any of the localized regions 140 that may have been formed during formation of the crystalline semiconductor material 120 and the amorphous material 142, may be mitigated by the treatment acts and contact resistance in the resulting apparatus 100 may be reduced. Accordingly, the contact structures 130 in the apparatus 100 according to embodiments of the disclosure may be substantially free of oxygen atoms, chlorine atoms, and nitrogen atoms adjacent to the interface 144 of the crystalline semiconductor material 120 and the amorphous material 142. Further, the oxygen atoms, chlorine atoms, and/or nitrogen atoms may be displaced without incurring damage to the crystalline semiconductor material 120 along the interface 144.

After forming the amorphous material 142 and, optionally, exposing the materials to the annealing conditions, at least a portion (e.g., an upper portion) of the amorphous material 142 may be converted to the metal silicide 122, as shown in FIG. 2C. The metal silicide 122 is adjacent to (e.g., over) the crystalline semiconductor material 120. In some embodiments, the metal silicide 122 is within portions (e.g., the upper portions) of the amorphous material 142 and additional portions (e.g., lower portions) of the amorphous material 142 may lack (e.g., not include) the metal silicide 122, as shown in FIG. 2C. Alternatively, and as shown in FIG. 2D, substantially all of the amorphous material 142 may be converted to the metal silicide 122 such that the metal silicide 122 is directly adjacent to (e.g., directly over) the crystalline semiconductor material 120 along the upper boundary 138 (FIG. 2B) thereof. The metal silicide 122 may be formed by a silicidation process that is conducted after cleaning the openings 136 and the amorphous material 142. By way of example only, a dilute hydrogen fluoride (300:1 water:hydrogen fluoride) wet etch chemistry may be used to clean the openings 136.

The metal silicide 122 may be formed by a CVD process, initially forming a metal adjacent to the crystalline semiconductor material 120. Conditions of the CVD process may cause the metal to react with silicon atoms in the crystalline semiconductor material 120, producing the metal silicide 122 adjacent to the crystalline semiconductor material 120. Alternatively, the metal may be annealed to form the metal silicide 122. The metal of the metal silicide 122 may be a transition metal including, but not limited to, cobalt, molybdenum, nickel, palladium, platinum, tantalum, titanium, or tungsten. The metal silicide 122 may, therefore, be cobalt silicide (CoSi), molybdenum silicide (MoSi), nickel silicide (NiSi), palladium silicide (PdSi), platinum silicide (PtSi), tantalum silicide (TaSi), titanium silicide (TiSi), or tungsten silicide (WSi). During the CVD process or a subsequently conducted anneal act, the metal atoms react with silicon atoms of the amorphous material 142. By way of example only, the metal (e.g., titanium) may be sputtered from the metal target into the openings 136 to form about 3 nm of the metal, conducting an additional rapid thermal anneal (RTA) act at about 660° C. for about 25 seconds, and using a wet etch chemistry to remove excess metal material.

The CVD process may use a metal precursor material that includes the metal and chlorine atoms or other reactive ligands. By way of non-limiting example, if titanium is to be formed as the metal, the metal precursor material may be a titanium precursor material, such as titanium tetrachloride (TiCl₄). However, other titanium precursor materials may be used. If an increased silicon content is desired in the metal silicide 122, silane may be used as a silicon precursor material and introduced during the CVD process.

With the silicidation act, a portion, such as an upper portion, of the amorphous material 142 is converted to the metal silicide 122. The metal silicide 122 may be formed at a thickness of from about 1 nm to about 5 nm, although other thicknesses may be contemplated. The metal silicide 122 is in direct contact with the amorphous material 142 or, alternatively, the crystalline semiconductor material 120. In some embodiments, the metal silicide 122 is titanium silicide (TiSi). The amorphous material 142 and the metal silicide 122 of the apparatus 100, therefore, substantially lack tungsten silicide (WSi) and polycrystalline silicon. In comparison, conventional contacts include a polycrystalline silicide in direct contact with a polycrystalline silicon, which directly contacts the monocrystalline silicon. In embodiments including the treated portions 121 (FIG. 2B) including the HCl formed within the upper portions of the crystalline semiconductor material 120 prior to forming the amorphous material 142, the extent of the impurity regions 140a and the defect regions 140b of the localized regions 140 may be effectively reduced compared to conventional contacts that have not been treated with HCl prior to conducting the silicidation process. For example, volumes (e.g., sizes, shapes) of individual localized regions 140 and/or occurrences of the localized regions 140 may be reduced.

As shown in FIG. 2D, formation of the metal silicide 122 results in formation of a conductive plug 145 (e.g., an epitaxial plug, a doped epitaxial plug, such as a phosphorus doped epitaxial plug, a doped laser anneal plug, such as a phosphorus doped laser anneal plug) adjacent to the active areas 104. The crystalline semiconductor material 120, the amorphous material 142 (not shown), if present, and the metal silicide 122 constitute the conductive plug 145. The metal material 126 may be formed over (e.g., directly on) the metal silicide 122 and between the digit line structures 118 (FIG. 1) and adjacent portions of the insulative spacer material 112. The metal of the metal silicide 122 and the metal material 126 may be formed in a single, substantially continuous process followed by the anneal act. By adjusting the conditions of the CVD process, such as the temperature or relative concentrations of the metal precursor material to other precursor materials (e.g., silane), the metal material 126 may be formed over the metal silicide 122 using a single, continuous CVD process. For example, the metal material 126 may be formed within and over the amorphous material 142 and the anneal act may be conducted to form the metal silicide 122 and the metal material 126, without forming a barrier material (e.g., a metal nitride) over the metal silicide 122. Therefore, no barrier material intervenes between the metal silicide 122 and the metal material 126. Accordingly, the metal silicide 122 is substantially devoid of nitrogen.

In some embodiments, the metal material 126 may be formed (e.g., deposited) using a pulsed-CVD process. For example, the pulsed-CVD process may include applying alternating cycles of a plasma. In some embodiments, a titanium material may be formed during intervals of the alternating cycles in which the plasma is applied. During additional intervals in which the plasma is not applied, additional materials (e.g., HCL, titanium chloride) may remove (e.g., etch) portions of unreacted titanium material, and may facilitate or enhance selectivity of the metal material 126.

In additional embodiments, the metal material 126 may be formed (e.g., deposited) using a PVD process. For example, the PVD process may include one or more process acts including sputtering the metal material from a metal target, molecular beam epitaxy (MBE), and electron beam deposition, although additional process conditions may be contemplated. In some embodiments, the titanium material of the metal material 126 may be formed (e.g., deposited) directly on the conductive plug 145 and a thin layer of a tungsten nitride material may be formed (e.g., deposited) on the titanium material. The materials of the metal material 126 may be exposed to annealing conditions following formation thereof, and may facilitate or enhance silicidation.

At the processing stage of FIG. 2D, the insulative spacer material 112 may include substantially straight, vertical sidewalls, without voids (e.g., spaces). The metal material 126 may be formed by conventional techniques. The metal material 126 may be a transition metal, a metal alloy, a metal nitride, a metal silicide, a metal carbide, or a metal oxide including, but not limited to, tungsten, titanium, nickel, platinum, gold, rhodium, iridium, ruthenium, ruthenium oxide, titanium nitride, tantalum nitride, tungsten nitride, titanium aluminum nitride, or alloys thereof. In some embodiments, the metal material 126 is titanium and is substantially devoid of tungsten. By way of non-limiting example, the metal material 126 may be formed using a metal precursor material, such as titanium tetrachloride (TiCl₄), hydrogen (H₂), and ammonia (NH₃).

Without being bound by any theory, it is believed that the chlorine atoms in the crystalline semiconductor material 120 may react with silicon atoms, breaking phosphorus-silicon bonds and forming silicon-chlorine bonds in the crystalline semiconductor material 120. When exposed to the metal precursor material, the silicon-chlorine bonds break and metal-silicon bonds form, forming the metal silicide 122 and HCl. If, for example, the crystalline semiconductor material 120 includes a phosphorus doped, crystalline silicon material, the crystalline semiconductor material 120 includes phosphorus atoms, oxygen atoms, and chlorine atoms bonded to the silicon atoms. The chlorine atoms may be present from HCl used to clean the crystalline semiconductor material 120 or from HCl formed during the silicidation and subsequent process acts. Substitutional phosphorus leads to an extra electron, creating n-type silicon. If titanium silicide is to be formed as the metal silicide 122, such as by using titanium tetrachloride (TiCl₄), hydrogen (H₂), and ammonia (NH₃), the highly electronegative chlorine atoms in the semiconductor material 120 react with hydrogen to form HCl and the titanium and silicon atoms react to form titanium-silicon bonds. Since the chlorine atoms accumulate at the top of the conductive plug 145, proximal to the phosphorus atoms, the TiCl₄, H₂, and NH₃, are easily reacted and improve the interface 144. Substitutional reactions of the dopant atoms and silicon atoms of the crystalline semiconductor material 120 and the titanium chloride of the metal material 126 may result in formation of relatively low concentrations of chlorine and/or oxygen within the metal silicide 122, which may result in a cleaner surface at the interface 144.

The metal material 126 may be formed using one or more conventional deposition processes. In some embodiments, the metal material 126 may be formed using a CVD process, without using a PVD process. Accordingly, the metal material 126 may be characterized as a “CVD metal” material. By decreasing the relative concentrations of silane to the metal precursor material, the metal material 126 may be formed over the metal silicide 122 by the substantially continuous CVD process. For example, the metal material 126 may substantially comprise titanium atoms without including silicon atoms, which may result in a cleaner surface at the interface 144. By using the CVD process, the metal (e.g., the titanium) of the metal material 126 may be present in (e.g., evenly distributed throughout) the conductive plug 145, compared to conductive plugs of conventional contacts including titanium formed by PVD processes without including chlorine. Further, one or more of the titanium atoms and chlorine atoms of the conductive plug 145 may extend within portions of the crystalline semiconductor material 120 of the apparatus 100. For example, the amorphous material 142 may be formed to exhibit a thickness of between about 2 nm and about 5 nm (e.g., about 3 nm), and at least some of the materials (e.g., titanium) of the metal material 126 may penetrate (e.g., extend beyond) the thickness of the amorphous material 142 and into the crystalline semiconductor material 120.

Following formation of the metal material 126, one or more additional process acts may be performed. The metal material 126 and the metal silicide 122 may be subjected to (e.g., exposed to) one or more treatment acts that change distribution of the dopants throughout the materials to diffuse the dopants through (e.g., from the upper portions to lower portions of) one or more of the metal silicide 122, the amorphous material 142 (not shown), if present, and the crystalline semiconductor material 120. The treatment act may include exposing the materials to additional annealing conditions including, for example, the RTA conditions. Subsequent process acts may be conducted to form the cell contacts 128 from the metal material 126. For example, the metal material 126 may be patterned by conventional photolithography and etch techniques to form the cell contacts 128, as shown in FIGS. 1 and 2D. The conductive plug 145 may vertically intervene between the cell contacts 128 and the active areas 104.

Contact structures 130 similar to that shown in FIG. 1 may be prepared as described above for FIGS. 2A through 2D. Formation of the contact structures 130 may include using an implant process following formation of the crystalline semiconductor material 120 and conducting an anneal act following formation of the metal material 126 using the CVD process. By way of non-limiting example, formation of the conductive plug 145 may include formation (e.g., epitaxially growth) of the crystalline semiconductor material 120 (e.g., epitaxial silicon) over the active areas 104 using, for example, dichlorosilane (DCS), phosphane (PH₃), and hydrogen chloride (HCl), although other precursor materials and process conditions may be contemplated. Following formation of the crystalline semiconductor material 120, the amorphous material 142 may be formed by the implant (e.g., PAI) process using one or more of Ge, P, As, and Sb (e.g., As, Sb) as the dopant, followed by forming a metal adjacent to the amorphous material 142. The amorphous material 142 and the metal may be converted to the metal silicide 122 using the silicidation process, and the metal material 126 may be formed over the metal silicide 122. The metal material 126 may be formed using precursors including titanium chloride, such as titanium tetrachloride (TiCl₄), hydrogen (H₂), and ammonia (NH₃). Formation of the metal material 126 may, optionally, include flowing a silicon precursor, such as silane (SiH₄) gas during formation thereof using the CVD process. Further, it is believed that an increased concentration of the dopants (e.g., phosphorus dopants) may improve so-called “dopant segregation” within the upper portions of the crystalline semiconductor material 120 to provide an increased concentration of the chlorine available to react with the precursors of the metal material 126. The anneal act (e.g., RTA) may be performed following formation of the metal material 126, and subsequent process acts may be conducted to form the cell contacts 128 from the metal material 126.

In other embodiments, formation of the contact structures 130 may include using the implant process following formation of the crystalline semiconductor material 120 and conducting an anneal act following the implant process and prior to forming the metal silicide 122 and the metal material 126 using the CVD process. By way of non-limiting example, formation of the conductive plug 145 (e.g., an epitaxial plug) may include formation of the crystalline semiconductor material 120 (e.g., crystalline silicon material) over the active areas 104 and formation of the amorphous material 142 using the implant process. The crystalline semiconductor material 120 may be exposed to the annealing conditions (e.g., RTA) to diffuse one or more dopants (e.g., phosphorus) from upper portions of the crystalline semiconductor material 120 into lower portions thereof after performing the implant process and prior to forming the metal silicide 122. It is believed that exposing the crystalline semiconductor material 120 to the annealing conditions prior to forming the metal silicide 122, may diffuse the dopants into so-called “substitutional points” in the silicon lattice prior to metallization, which may reduce contact resistance of the conductive plug 145. Exposing the crystalline semiconductor material 120 to the anneal conditions may also repair any damage that may have occurred within the crystalline semiconductor material 120 during the implant process acts. An additional anneal act (e.g., RTA) may, optionally, be performed following formation of the metal material 126 (e.g., using TiCl₄, H₂, and NH₃).

In yet other embodiments, formation of the contact structures 130 may include conducting additional treatment acts (e.g., exposing the crystalline semiconductor material 120 to a wet etch chemistry) prior to using the implant process. As in the previous embodiment, an anneal act may be conducted following the implant process and prior to forming the metal silicide 122 and the metal material 126 using the CVD process. By way of non-limiting example, formation of the conductive plug 145 (e.g., an epitaxial plug) may include forming the crystalline semiconductor material 120, forming the amorphous material 142 using the implant process, and exposing the crystalline semiconductor material 120 to the annealing conditions prior to forming the metal silicide 122. Additional treatment acts may include exposing the crystalline semiconductor material 120 to a wet etch chemistry including, for example, HCl. Formation of the HCl and diffusion of the chlorine atoms within the treated portions 121 of the crystalline semiconductor material 120 may allow a relatively greater concentration of chlorine atoms proximate to the upper boundary 138 thereof to achieve a desired chemical composition for formation of the metal material 126 (e.g., TiCl₄, H₂, and NH₃).

In additional embodiments, formation of the contact structures 130 may include forming the crystalline semiconductor material 120 using an anneal act, without epitaxially growing the crystalline semiconductor material 120 over the active areas 104. The implant process may be used following formation of the crystalline semiconductor material 120, and an anneal act may be conducted following the implant process and prior to forming the metal silicide 122 and the metal material 126 using the CVD process. By way of non-limiting example, formation of the conductive plug 145 (e.g., a laser anneal plug) may include forming the crystalline semiconductor material 120 by conducting one or more anneal acts (e.g., a laser anneal act), without using the epitaxial growth process of the previous examples. For example, one or more materials (e.g., amorphous material) may be formed over the active areas 104 and the anneal acts may be conducted to convert the materials to a crystalline material, resulting in formation of the crystalline semiconductor material 120. The additional treatment acts including exposing the crystalline semiconductor material 120 to a wet etch chemistry (e.g., HCl) may, optionally, be performed following formation thereof. The amorphous material 142 may be formed using the implant process and the crystalline semiconductor material 120 may be exposed to the annealing conditions prior to forming the metal silicide 122. The metal material 126 (e.g., TiCl₄, H₂, and NH₃) may be formed over the metal silicide 122.

For clarity and case of understanding the drawings and associated descriptions, the previous embodiments of forming the contact structures 130 are described separately. However, it is understood that certain process conditions of the individual embodiments may be combined. For example, the crystalline semiconductor material 120 may be exposed to the wet etch chemistry (e.g., HCl) during or, alternatively, following formation thereof. Test results of samples of the contact structures 130, including the materials and process acts of the previous embodiments, showed a reduction in contact resistance by about 35 percent, or even a higher percentage (e.g., about 50 percent). These results were unexpected and surprising given multiple variables (e.g., multiple ways) of forming the metal silicide 122. Therefore, it was determined that using the titanium chloride material (e.g., TiCl₄, H₂, and NH₃) of the metal material 126, as well as using the additional treatment acts (e.g., HCl, annealing conditions) prior to forming the metal silicide 122, improved dopant segregation and improved homogeneous distribution of the dopants throughout the crystalline semiconductor material 120, resulting in a cleaner surface at the interface 144.

Accordingly, a method of forming an apparatus is disclosed. The method comprises forming a crystalline semiconductor material comprising one or more of a monocrystalline material and a nanocrystalline material adjacent to active areas of memory cells, forming an amorphous material within portions of the crystalline semiconductor material, forming a metal material comprising one or more of chlorine atoms and nitrogen atoms over the amorphous material, converting a portion of the amorphous material and the metal material to form a metal silicide material adjacent to the crystalline semiconductor material, forming cell contacts over the metal silicide material, and forming a storage node adjacent to the cell contacts.

Accordingly, an apparatus comprising a memory array comprising word lines, bit lines, and memory cells. Each memory cell is coupled to an associated word line and an associated bit line and each memory cell comprises an access device, a crystalline silicon material comprising one or more of a monocrystalline silicon material and a nanocrystalline silicon material over the access device, a metal silicide material over the crystalline silicon material, a metal contact material over the metal silicide material, and a storage node over the metal contact material. The metal contact material comprises titanium chlorine atoms and is substantially devoid of tungsten.

FIGS. 3A through 3D show simplified, partial cross-sectional views of a method of forming an apparatus formed by additional process acts than process acts used to form the apparatus 100. FIG. 3A illustrates a simplified, partial cross-sectional view of an apparatus 100′. As illustrated in FIGS. 3A through 3D, the apparatus 100′ may be formed to include the crystalline semiconductor material 120 (e.g., the monocrystalline material 120′, the nanocrystalline material 120″) over the active areas 104. The apparatus 100′ may be formed to include the crystalline semiconductor material 120 over the active areas 104 using process acts (e.g., deposition process acts and treatment acts, such as exposing materials to annealing conditions) that differ from the process acts of the embodiments of FIGS. 2A through 2D.

As shown in FIG. 3A, the crystalline semiconductor material 120 including one or more of the monocrystalline material 120′ and the nanocrystalline material 120″ may be formed over (e.g., on, directly on) the active areas 104. For clarity and case of understanding the drawings and associated descriptions, the nanocrystalline material 120″ includes multiple crosshatchings to illustrate the multi-directional crystal orientations within the nanocrystalline material 120″. The crystalline semiconductor material 120 may be doped, such as with an n-type dopant. The crystalline semiconductor material 120 may, for example, be implanted with phosphorus atoms (e.g., P-doped crystalline silicon material) or other dopant atoms. The silicon of the active areas 104 functions as a seed material to orient crystal forms of the crystalline semiconductor material 120 (e.g., the monocrystalline material 120′). The monocrystalline material 120′ functions as a seed material to orient one or more additional crystal forms of the nanocrystalline material 120″, if present.

A first portion (e.g., an initial portion, a lower portion) of the crystalline semiconductor material 120 may initially be formed over the active areas 104. The first portion of the crystalline semiconductor material 120 may be formed to exhibit an initial upper boundary 137 (e.g., an initial upper surface), as shown in FIG. 3A. In some embodiments, the first portion of the crystalline semiconductor material 120 may include the monocrystalline material 120′ (e.g., only) over the active areas 104 without including the nanocrystalline material 120″. However, it is also contemplated that the first portion of the crystalline semiconductor material 120 may additionally, or alternatively, include the nanocrystalline material 120″ over the active areas 104. For example, the crystalline semiconductor material 120 may be formed to include the nanocrystalline material 120″ over (e.g., directly on) the active areas 104, without forming the monocrystalline material 120′.

After forming the first portion of the crystalline semiconductor material 120 and prior to forming additional portions thereof, one or more additional process acts may be performed. For example, the first portion of the crystalline semiconductor material 120 may be subjected to (e.g., exposed to) one or more treatment acts that change distribution of the dopants throughout the materials to diffuse the dopants through (e.g., from the upper portions to lower portions of) the crystalline semiconductor material 120. The treatment acts may include exposing the materials to initial (e.g., first) annealing conditions including, for example, the RTA conditions. Accordingly, the crystalline semiconductor material 120 may be annealed (e.g., thermally annealed) before forming additional portions thereof. Annealing the crystalline semiconductor material 120 may diffuse the dopants from the upper portions into the lower portions of the crystalline semiconductor material 120, and may also facilitate or enhance dopant activation.

As shown in FIG. 3B, a second portion (e.g., an additional portion, an upper portion) of the crystalline semiconductor material 120 may be formed over the first portion thereof following the treatment acts that expose the materials to the initial annealing conditions (e.g., a first anneal act). The second portion of the crystalline semiconductor material 120 may be formed to exhibit the upper boundary 138. The second portion of the crystalline semiconductor material 120 of FIG. 3B may include one or more of the monocrystalline material 120′ and the nanocrystalline material 120″. In some embodiments, the first portion of the crystalline semiconductor material 120 may at least partially (e.g., substantially entirely) be formed of the monocrystalline material 120′, and the second portion thereof may at least partially (e.g., substantially entirely) be formed of the nanocrystalline material 120″, although other configurations may be contemplated. In some embodiments, the second portion of the crystalline semiconductor material 120 may include a relatively greater volume of the nanocrystalline material 120″ than the lower portion thereof.

After forming the second portion of the crystalline semiconductor material 120, the first portion and the second portion of the crystalline semiconductor material 120 may be subjected to (e.g., exposed to) additional treatment acts including exposing the materials to additional annealing conditions (e.g., a second anneal act). Accordingly, formation of the crystalline semiconductor material 120 may be cyclical (e.g., occurring in cycles, regularly repeated). Annealing the crystalline semiconductor material 120 may diffuse the dopants from the upper portions (e.g., the second portion) into the lower portions (e.g., the first portion) of the crystalline semiconductor material 120, and may also facilitate or enhance dopant activation. While FIGS. 3A and 3B depict formation of the crystalline semiconductor material 120 using two (2) cycles of material formation process acts separated by anneal acts, the disclosure is not so limited and the crystalline semiconductor material 120 may be formed using more than two (e.g., three (3) or more) cycles.

As shown in FIG. 3B, the crystalline semiconductor material 120 of the apparatus 100′ may be formed to include a doped region 146 including one or more dopants (e.g., an n-type dopant). In some embodiments, the doped region 146 of the crystalline semiconductor material 120 may exhibit a substantially heterogeneous distribution of the dopants within the material thereof. For example, the doped region 146 of the crystalline semiconductor material 120 may include a relatively high doped region 146′ over the active areas 104 and a relatively low doped region 146″ over the relatively high doped region 146′. The relatively high doped region 146′ may include a relatively greater concentration of the dopants (e.g., phosphorus) than the relatively low doped region 146″. The relatively greater concentration of the dopants of the relatively high doped region 146′ may be responsive to conducting the first anneal act after (e.g., immediately after) forming the first portion of the crystalline semiconductor material 120 and prior to forming the second portion thereof, and thereafter conducting the second anneal. By way of non-limiting example, a concentration of the dopant atoms within the crystalline semiconductor material 120 (e.g., within the relatively high doped region 146′ of the doped region 146) may be within a range of from about 3 atomic percent to about 6 atomic percent. Accordingly, the concentration of the dopant atoms within the crystalline semiconductor material 120 may be at least about two times (2×) greater than a concentration of dopant atoms of crystalline material of conventional contact structures, such as about three times (3×) greater than a concentration of dopant atoms.

In embodiments including the monocrystalline material 120′ within the first portion of the crystalline semiconductor material 120 and the nanocrystalline material 120″ within the second portion thereof, the relatively high doped region 146′ may include the monocrystalline material 120′ without including the nanocrystalline material 120″, and the relatively low doped region 146″ may include the nanocrystalline material 120″ without including the monocrystalline material 120′. Thus, diffusion of the dopants within the crystalline semiconductor material 120 may be enhanced by using the cyclical process, such that the concentration of the dopants proximate to the upper boundary 138 thereof may be reduced compared to diffusion of dopants within conventional contacts. The reduced concentration of the dopants proximate to the upper boundary 138 may allow for an increased concentration of chlorine at the upper boundary 138.

In additional embodiments, the doped region 146 of the crystalline semiconductor material 120 may exhibit a substantially homogeneous distribution of the dopants within the material thereof. The homogeneous distribution of dopants of the doped region 146 may extend substantially continuously throughout the crystalline semiconductor material 120. As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature.

In some embodiments, forming the crystalline semiconductor material 120 using the two or more cycles of material formation process acts separated by the treatment acts (e.g., annealing) to expose the materials to the annealing conditions may diffuse portions of the dopants through (e.g., substantially entirely through) the crystalline semiconductor material 120 and into a material (e.g., silicon material) of the active areas 104, resulting in formation of an interface region 148, as shown in FIG. 3B by the dashed lines. The interface region 148 may be defined by portions (e.g., upper portions) of the active areas 104 and portions (e.g., lower portions) of the crystalline semiconductor material 120 including the dopants (e.g., phosphorus) of the relatively high doped region 146′ of the doped region 146. Accordingly, the interface region 148 includes one or more materials (e.g., P-doped crystalline semiconductor material 120, P-doped material of the active areas 104) without including a single, well-defined interface therebetween. A transition between the individual materials of the interface region 148 may exhibit a gradual transition that varies continuously (e.g., changes progressively) from the crystalline semiconductor material 120 to the material of the active areas 104 with no readily discernable physical interface therebetween.

As shown in FIG. 3C, at least a portion (e.g., the upper portion) of the amorphous material 142 may be converted to the metal silicide 122. For example, upper portions of the crystalline semiconductor material 120 may be converted to the amorphous material 142 and portions (e.g., upper portions, an entirety) of the amorphous material 142 may be converted to the metal silicide 122. Portions of the amorphous material 142 may or may not remain in the apparatus 100′ depending on the extent of the amorphous material 142 converted to the metal silicide 122. In some embodiments, the metal silicide 122 directly contacts the crystalline semiconductor material 120, and the crystalline semiconductor material 120 is directly between the active areas 104 and the metal silicide 122.

The apparatus 100′ may include the localized regions 140 including one or more of the impurity regions 140a and the defect regions 140b that may be formed during the formation of the crystalline semiconductor material 120 followed by formation of the amorphous material 142 using the implant process. The impurity regions 140a may include one or more of oxygen (O₂) and chlorine (Cl), for example. The defect regions 140b may include voids (e.g., gaps, spaces) separating adjacent regions of the crystalline material of the crystalline semiconductor material 120 from one another.

Without being bound by any theory, formation of the crystalline semiconductor material 120 using the cyclical process may decrease the presence of the localized regions 140, facilitating a reduction in sizes and/or amounts of the impurity regions 140a and the defect regions 140b. For example, annealing the crystalline semiconductor material 120 using the two or more cycles during formation thereof may allow increased concentration of the dopants within the relatively high doped region 146′ of the doped region 146 proximate lower boundaries of the crystalline semiconductor material 120 (e.g., within the interface region 148). Further, annealing the crystalline semiconductor material 120 using the cyclical process may allow a reduced concentration of the dopants within the relatively low doped region 146″ of the doped region 146, as well as allowing the dopants to diffuse heterogeneously throughout the material thereof. Accordingly, the localized regions 140 within the crystalline semiconductor material 120 (e.g., proximate to the interface 144 of the amorphous material 142 and crystalline semiconductor material 120) may be mitigated and contact resistance may be reduced. In some embodiments, contact resistance may be reduced by about 35 percent, or even a higher percentage (e.g., about 50 percent), compared to contact resistance of conventional apparatus.

As shown in FIG. 3D, formation of the metal silicide 122 results in formation of the conductive plug 145. The metal material 126 may be formed over the metal silicide 122 and between the adjacent portions of the insulative spacer material 112 to form the cell contacts 128. The conductive plug 145 of the contact structures 130 (FIG. 1) may include the crystalline semiconductor material 120, the amorphous material 142, if present, and the metal silicide 122.

Contact structures 130 similar to that shown in FIG. 1 may be prepared as described above for FIGS. 3A through 3D. Formation of the contact structures 130 may include using an implant process following formation of the crystalline semiconductor material 120 using a cyclical process and conducting an anneal act prior to forming the metal silicide 122 and the metal material 126 using the CVD process. By way of non-limiting example, formation of the conductive plug 145 (e.g., an epitaxial plug) may include formation of the crystalline semiconductor material 120 over the active areas 104 using DCS, PH₃, and HCl. The crystalline semiconductor material 120 may be formed using two (2) or more cycles of material formation and treatment acts. For example, a first portion of the crystalline semiconductor material 120 may initially be formed over the active areas 104, followed by subjecting (e.g., exposing) the first portion to treatment acts including initial (e.g., first) annealing (e.g., RTA) conditions. A second portion of the crystalline semiconductor material 120 may be formed over the first portion thereof following the treatment acts that expose the materials to the initial annealing conditions. After forming the second portion of the crystalline semiconductor material 120, the first portion and the second portion thereof may be subjected to treatment acts including additional annealing conditions (e.g., a second anneal act). Conducting the treatment acts including annealing the crystalline semiconductor material 120 in two or more cycles may diffuse the dopants from the upper portions into the lower portions of the crystalline semiconductor material 120, and may also facilitate or enhance dopant activation. For example, the crystalline semiconductor material 120 may include a relatively high doped region including a relatively greater concentration of dopants (e.g., phosphorus) over and within the active areas 104 and a relatively low doped region over the relatively high doped region. It is believed that the cyclical process may improve dopant segregation, as well as improving an interface within the interface region 148 between the active areas 104 and the crystalline semiconductor material 120.

The additional treatment acts including exposing the crystalline semiconductor material 120 to a wet etch chemistry (e.g., HCl) may, optionally, be performed following formation of the second portion thereof. Thereafter, the amorphous material 142 may be formed using the implant process. The crystalline semiconductor material 120 may be exposed to additional annealing (e.g., RTA) conditions after performing the implant process and prior to forming the metal silicide 122. The amorphous material 142 and the metal may be converted to the metal silicide 122, and the metal material 126 (e.g., TiCl₄, H₂, and NH₃) may be formed over the metal silicide 122. Formation of the metal material 126 may, optionally, include flowing the silicon precursor (e.g., SiH₄ gas) during formation thereof. An additional anneal act may, optionally, be performed following formation of the metal material 126, and subsequent process acts may be conducted to form the cell contacts 128 from the metal material 126.

In additional embodiments, formation of the contact structures 130 may include using the implant process following formation of the crystalline semiconductor material 120 using the cyclical process and conducting an anneal act following formation of the metal material 126 using the CVD process. By way of non-limiting example, formation of the conductive plug 145 (e.g., an epitaxial plug) may include formation of the crystalline semiconductor material 120 in two or more cycles, as described in the previous example. The amorphous material 142 may be formed using the implant process, followed by formation of the metal silicide 122 and the metal material 126 (e.g., TiCl₄, H₂, and NH₃). The anneal act (e.g., RTA) may be performed following formation of the metal material 126, without conducting the additional anneal act after performing the implant process and prior to forming the metal of the metal silicide 122.

Accordingly, a method of forming an apparatus according to additional embodiments of the disclosure is disclosed. The method comprises forming a first portion of a crystalline semiconductor material adjacent to active areas of memory cells, annealing the first portion of the crystalline semiconductor material, forming a second portion of the crystalline semiconductor material over the first portion, annealing the first portion and the second portion of the crystalline semiconductor material, forming an amorphous material over the second portion of the crystalline semiconductor material, forming a metal material over the amorphous material, converting a portion of the amorphous material and the metal material to a metal silicide material, forming cell contacts over the metal silicide material, and forming a storage node adjacent to the cell contacts.

Although one or more of the apparatus 100, 100′ is described herein as including a memory device including a memory array of a dynamic random access memory (DRAM) device, the disclosure is not so limited. By way of non-limiting example, the apparatus 100, 100′ may be used within additional memory devices including FLASH memory configured as a not-and (NAND), not-or (NOR), 3D XPoint memory devices, or other memory devices. Such configurations may facilitate a higher density of the memory array relative to conventional memory devices.

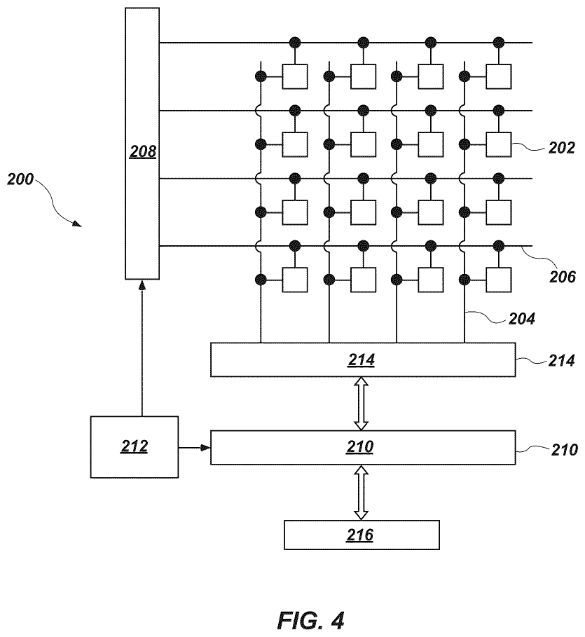

The apparatus 100, 100′ may be subjected to additional processing acts, as desired, to form an electronic device 200 (e.g., a memory device) including the apparatus 100, 100′, as shown in FIG. 4. Such additional processing may employ conventional processes and conventional processing equipment. The electronic device 200 may include, for example, embodiments of the apparatus 100, 100′ previously described herein. As shown in FIG. 4, the electronic device 200 may include memory cells 202, digit lines 204 (e.g., bit lines), word lines 206 (e.g., access lines), a row decoder 208, a column decoder 210, a memory controller 212, a sense device 214, and an input/output device 216.

The memory cells 202 of the electronic device 200 are programmable to at least two different logic states (e.g., logic 0 and logic 1). Each memory cell 202 may individually include a capacitor and transistor (not shown) and the contact structure 130 according to embodiments of the disclosure. The capacitor stores a charge representative of the programmable logic state (e.g., a charged capacitor may represent a first logic state, such as a logic 1; and an uncharged capacitor may represent a second logic state, such as a logic 0) of the memory cell 202. The transistor grants access to the capacitor upon application (e.g., by way of one of the word lines 206) of a minimum threshold voltage to a semiconductive channel thereof for operations (e.g., reading, writing, rewriting) on the capacitor.

The digit lines 204 are connected to the capacitors of the memory cells 202 by way of the transistors of the memory cells 202. The word lines 206 extend perpendicular to the digit lines 204, and are connected to gates of the transistors of the memory cells 202. Operations may be performed on the memory cells 202 by activating appropriate digit lines 204 and word lines 206. Activating a digit line 204 or a word line 206 may include applying a voltage potential to the digit line 204 or the word line 206. Each column of memory cells 202 may individually be connected to one of the digit lines 204, and each row of the memory cells 202 may individually be connected to one of the word lines 206. Individual memory cells 202 may be addressed and accessed through the intersections (e.g., cross points) of the digit lines 204 and the word lines 206.

The memory controller 212 may control the operations of the memory cells 202 through various components, including the row decoder 208, the column decoder 210, and the sense device 214. The memory controller 212 may generate row address signals that are directed to the row decoder 208 to activate (e.g., apply a voltage potential to) predetermined word lines 206, and may generate column address signals that are directed to the column decoder 210 to activate (e.g., apply a voltage potential to) predetermined digit lines 204. The memory controller 212 may also generate and control various voltage potentials employed during the operation of the electronic device 200. In general, the amplitude, shape, and/or duration of an applied voltage may be adjusted (e.g., varied), and may be different for various operations of the electronic device 200.

During use and operation of the electronic device 200, after being accessed, a memory cell 202 may be read (e.g., sensed) by the sense device 214. The sense device 214 may compare a signal (e.g., a voltage) of an appropriate digit line 204 to a reference signal in order to determine the logic state of the memory cell 202. If, for example, the digit line 204 has a higher voltage than the reference voltage, the sense device 214 may determine that the stored logic state of the memory cell 202 is a logic 1, and vice versa. The sense device 214 may include transistors and amplifiers to detect and amplify a difference in the signals. The detected logic state of a memory cell 202 may be output through the column decoder 210 to the input/output device 216. In addition, a memory cell 202 may be set (e.g., written) by similarly activating an appropriate word line 206 and an appropriate digit line 204 of the electronic device 200. By controlling the digit line 204 while the word line 206 is activated, the memory cell 202 may be set (e.g., a logic value may be stored in the memory cell 202). The column decoder 210 may accept data from the input/output device 216 to be written to the memory cells 202. Furthermore, a memory cell 202 may also be refreshed (e.g., recharged) by reading the memory cell 202. The read operation will place the contents of the memory cell 202 on the appropriate digit line 204, which is then pulled up to full level (e.g., full charge or discharge) by the sense device 214. When the word line 206 associated with the memory cell 202 is deactivated, all of memory cells 202 in the row associated with the word line 206 are restored to full charge or discharge.

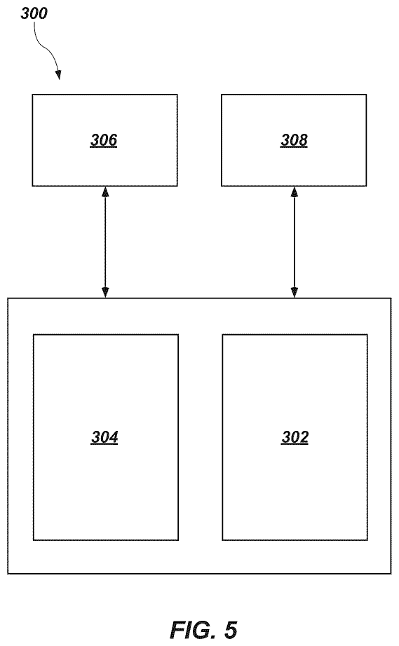

The apparatus 100, 100′ according to embodiments of the disclosure may be used in embodiments of electronic systems of the disclosure. For example, FIG. 5 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one electronic device 200. The electronic device 200 may comprise, for example, an embodiment of one or more of the apparatus 100, 100′ previously described herein. The electronic system 300 may further include at least one electronic signal processor device 304 (often referred to as a “microprocessor”). The electronic signal processor device 304 may, optionally, include an embodiment of the apparatus 100, 100′ previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the electronic device 302 and the electronic signal processor device 304.

While the disclosure is susceptible to various modifications and alternative forms, specific embodiments have been shown by way of example in the drawings and have been described in detail herein. However, the disclosure is not intended to be limited to the particular forms disclosed. Rather, the disclosure is to cover all modifications, equivalents, and alternatives falling within the scope of the disclosure as defined by the following appended claims and their legal equivalents.

What is claimed is:

1. A method of forming an apparatus, the method comprising:
forming a crystalline semiconductor material comprising one or more of a monocrystalline material and a nanocrystalline material adjacent to active areas of memory cells;
forming an amorphous material within portions of the crystalline semiconductor material;
forming a metal material comprising one or more of chlorine atoms and nitrogen atoms over the amorphous material;
converting a portion of the amorphous material and the metal material to form a metal silicide material adjacent to the crystalline semiconductor material;
forming cell contacts over the metal silicide material; and
forming a storage node adjacent to the cell contacts.

2. The method of claim 1, wherein forming the metal material and converting the portion of the amorphous material and the metal material comprises depositing a metal comprising titanium using a CVD process and annealing the metal to form the metal silicide material.

3. The method of claim 1, further comprising forming the metal material over the amorphous material and forming a metal contact material of the cell contacts in a single, substantially continuous process, without forming a nitride barrier material over the metal silicide material.

4. The method of claim 1, wherein forming the crystalline semiconductor material comprises forming an amorphous silicon material adjacent to the active areas of the memory cells, and conducting a laser anneal act to convert the amorphous silicon material to the crystalline semiconductor material.

5. The method of claim 1, wherein forming the amorphous material comprises substantially converting a phosphorus-doped crystalline silicon material using a pre-amorphization implant process to form a phosphorus-doped amorphous silicon material.

6. The method of claim 5, further comprising exposing the phosphorus-doped crystalline silicon material to annealing conditions to diffuse one or more dopants from upper portions of the crystalline semiconductor material into lower portions thereof after performing the pre-amorphization implant process and prior to forming the metal silicide material.

7. The method of claim 1, further comprising:
forming hydrogen chloride within upper portions of the crystalline semiconductor material; and
subjecting the crystalline semiconductor material to an implant process using one or more of arsenic and antimony to form the amorphous material.

8. The method of claim 1, wherein forming the crystalline semiconductor material comprises epitaxially growing the monocrystalline material on the active areas of the memory cells and forming the nanocrystalline material adjacent to the monocrystalline material in a single, substantially continuous process.

9. A method of forming an apparatus, the method comprising:
forming a first portion of a crystalline semiconductor material adjacent to active areas of memory cells;
annealing the first portion of the crystalline semiconductor material;
forming a second portion of the crystalline semiconductor material over the first portion;
annealing the first portion and the second portion of the crystalline semiconductor material;
forming an amorphous material over the second portion of the crystalline semiconductor material;
forming a metal material over the amorphous material;
converting a portion of the amorphous material and the metal material to a metal silicide material;
forming cell contacts over the metal silicide material; and
forming a storage node adjacent to the cell contacts.

10. The method of claim 9, further comprising subjecting the crystalline semiconductor material to an implant process using one or more of germanium, phosphorus, arsenic, and antimony to form an n-doped amorphous silicon material over the crystalline semiconductor material.

11. The method of claim 9, wherein forming the metal material over the amorphous material comprises exposing the amorphous material to titanium chloride, hydrogen, and ammonia.

12. The method of claim 9, wherein converting the portion of the amorphous material and the metal material to the metal silicide material comprises exposing the amorphous material to silane during formation of the metal material.

13. The method of claim 9, wherein converting the portion of the amorphous material and the metal material to the metal silicide material comprises thermal annealing the crystalline semiconductor material and the metal material after forming the metal material.

14. The method of claim 9, wherein:
forming the first portion of the crystalline semiconductor material comprises forming a relatively high doped region, and
forming the second portion of the crystalline semiconductor material comprises forming a low doped region, the relatively high doped region including a relatively greater concentration of an n-type dopant than the low doped region.

15. An apparatus, comprising:
a memory array comprising word lines, bit lines, and memory cells, each memory cell coupled to an associated word line and an associated bit line and each memory cell comprising:
an access device;
a crystalline silicon material comprising one or more of a monocrystalline silicon material and a nanocrystalline silicon material over the access device;
a metal silicide material over the crystalline silicon material;
a metal contact material over the metal silicide material, the metal contact material comprising titanium atoms and chlorine atoms, and the metal contact material substantially devoid of tungsten; and
a storage node over the metal contact material.

16. The apparatus of claim 15, further comprising opposing portions of an insulative material laterally adjacent to the crystalline silicon material and the metal silicide material, a width of the crystalline silicon material between the opposing portions of the insulative material within a range of from about 8 nm to about 10 nm.

17. The apparatus of claim 15, wherein the crystalline silicon material comprises the nanocrystalline silicon material directly adjacent to the access device and no monocrystalline silicon material directly adjacent to the access device.

18. The apparatus of claim 15, wherein the crystalline silicon material comprises crystalline silicon and the metal silicide material comprises titanium silicide, the crystalline silicon and the titanium silicide substantially devoid of polycrystalline silicon.

19. The apparatus of claim 15, wherein the crystalline silicon material and the metal silicide material comprise a conductive plug, the conductive plug substantially free of oxygen atoms and the chlorine atoms adjacent an interface between the crystalline silicon material and the metal silicide material.

20. The apparatus of claim 15, wherein the crystalline silicon material comprises a relatively highly doped region over the access device and a relatively low doped region over the relatively highly doped region, the relatively highly doped region comprising a concentration of an n-type dopant within a range of from about 3 atomic percent to about 6 atomic percent.
